(19) United States
(12) Patent Application Publication
(10) Pub. No.: US 2026/0150747 A1
(43) Pub. Date: May 28, 2026

(54) RING STRUCTURE FOR SUPPORTING LIQUID METAL IN A SEMICONDUCTOR PACKAGE

(71) Applicant: Taiwan Semiconductor Manufacturing Company, Ltd., Hsin-Chu (TW)

(72) Inventors: Hsin-Yu CHEN, Taipei City (TW); Yu-Hsiang HU, Hsinchu City (TW); Jyun-Siang PENG, Hsinchu City (TW); Chien-Hsun LEE, Chu-tung Town (TW); Kathy Wei YAN, Hsinchu (TW)

(21) Appl. No.: 18/957,254

(22) Filed: Nov. 22, 2024

(51) Int. Cl. H01L 23/00; H01L 23/31; H01L 23/367; H01L 23/473; H01L 23/498; H01L 25/065

(52) U.S. Cl. CPC H10W 74/121; H10W 40/22; H10W 40/47; H10W 70/65; H10W 90/00; H10W 72/387; H10W 72/877; H10W 74/15; H10W 90/724; H10W 90/736

(57) ABSTRACT

One aspect of the present disclosure pertains to a package structure. The package structure includes a die bonded to a substrate; a molding compound over the substrate and surrounding the die; a liquid metal over a top surface of the die; a ring structure over the molding compound and surrounding sidewalls of the liquid metal; and a heat sink attached to the ring structure and contacting the liquid metal. The ring structure includes an inner ring portion interfacing the liquid metal and an outer ring portion supporting the heat sink, and the inner ring portion includes through holes that form circulation channels for the liquid metal.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Demands for more power and more condensed chip space (e.g., in high performance computing (HPC) and artificial intelligence (AI) applications) require proportional advancements in thermal management. For example, in HPC and AI applications, a critical issue is the hot spot thermal dissipation of device dies within central processing units (CPUs) and graphical processing units (GPUs). In 2.5D or 3D IC structures, device dies are bonded to a package substrate (e.g., via an interposer) to form semiconductor packages. The heat generated by the device dies during operation needs to be properly dissipated to prevent performance degradation or even physical damage. To dissipate heat, a thermal interface material (TIM) layer may be formed over device dies to engage and thermally conduct the heat from the device dies to a heat sink. For example, a metal lid is formed over the TIM layer, and a heat sink is formed over the metal lid, and heat dissipates from the dies through the TIMs and the metal lid to the heat sink.

However, the heat dissipation efficiency in existing semiconductor packages require improvements in order to meet the power demands of data centers running HPC and AI workloads. Therefore, although existing semiconductor packages have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates an integrated circuit (IC) semiconductor package having a ring structure for supporting liquid metal over dies, according to an embodiment of the present disclosure.

FIG. 2 illustrates a portion of the IC semiconductor package of FIG. 1, according to an embodiment of the present disclosure.

FIG. 3 illustrates a ring structure for supporting liquid metal over dies, according to an embodiment of the present disclosure.

FIG. 4 illustrates a ring structure for supporting liquid metal over dies, according to another embodiment of the present disclosure.

FIGS. 5A-5B illustrate various top views of the IC semiconductor package of FIG. 1, according to various embodiments of the present disclosure.

FIGS. 6A-6E illustrate a mechanism of containing liquid metal using inlet and outlet valves in a ring structure, according to an embodiment of the present disclosure.

FIG. 7 illustrates various dimensions of a ring structure for supporting liquid metal over dies, according to an embodiment of the present disclosure

FIG. 8 illustrates a flow chart of a method to form an IC semiconductor package having a ring structure for supporting liquid metal over dies, in portion or in entirety, according to an embodiment of the present disclosure.

FIGS. 9-15 illustrate an IC semiconductor package (or a portion thereof) at intermediate stages of fabrication and processed in accordance with the method of FIG. 8, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

To address greater thermal loads of next-generation high power semiconductor devices, thermal management in backend package technology is one key component in improving energy efficiency. Improved energy efficiency better supports the complex IC requirements of AI, ML, and HPC. To that effect, the present disclosure describes directly using liquid metal as a thermal interface material (TIM) to conduct heat from dies to a heat sink. Liquid metal has extremely high thermal conductivity (compared to traditional TIMs). Further, liquid metal has malleable properties for superior thermal contact. However, due to thermal stress variations during device operation, package components may expand (e.g., during high heat operations) and thermally contract (e.g., during low heat operations), causing warpage and bending of device components. This may cause liquid metal loss due to the liquid metal overflowing or leaking into unintended locations. As such, the present disclosure describes IC package structures (e.g., semiconductor packages) that have ring structures to support liquid metal over dies. The ring structure constrains the liquid metal in a desired die area. Further, the ring structure provides a mechanism for containing the liquid metal in the event of package warpage during device operation. The mechanism prevents liquid metal from overflowing under thermal stress or physical stress. Specifically, the ring structure includes a buffer area for holding the liquid metal when the liquid metal begins to overflow. The buffer area temporarily holds the overflowed liquid metal and returns back the liquid metal to the desired area when conditions allow for it.

The various aspects of the present disclosure will now be described in more detail with reference to the figures. Throughout the present disclosure, unless expressly otherwise described, like reference numerals denote like features.

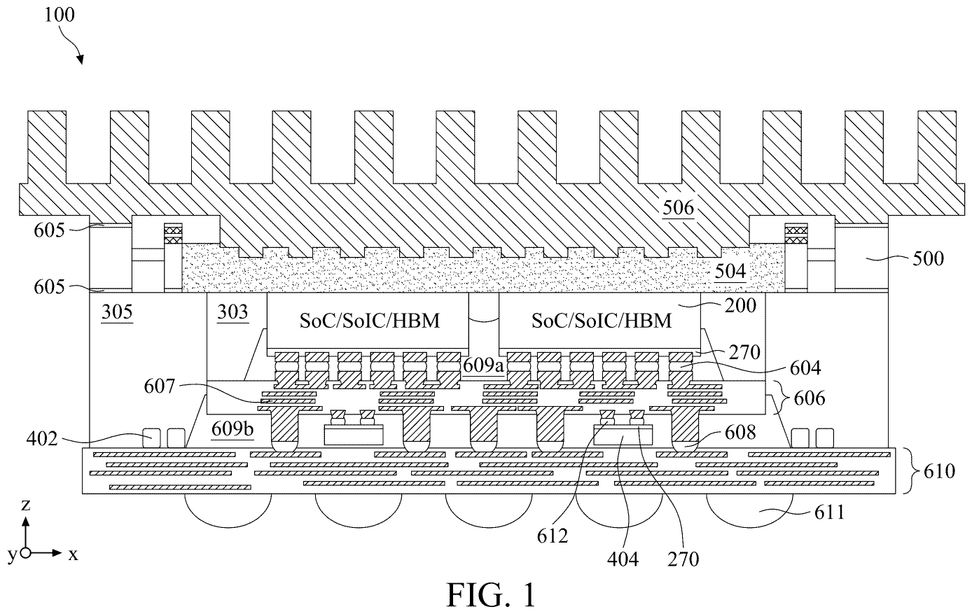

FIG. 1 illustrates an integrated circuit (IC) semiconductor package 100 having a ring structure 500 for supporting liquid metal 504 over dies 200, according to an embodiment of the present disclosure. The semiconductor package 100 may include 2.5D and/or 3D IC heterogenous integrated structures. In a 2.5D structure, at least two dies 200 are coupled to a redistribution layer (RDL) structure (e.g., interposer 606) that provides chip-to-chip communication. The at least two dies 200 in a 2.5D structure are not stacked one over another vertically. In a 3D structure, at least two dies 200 are stacked one over another and interact with each other by way of through silicon vias (TSVs) (not explicitly shown). The 2.5D and 3D structures may combine high bandwidth memory (HBM) and system-on-chip (SoC) dies into a single semiconductor package 100. An SoC die combines elements of a computing or electronic system such as CPU, memory, etc., that were originally in separate chips. Some of the SoC dies may be system-on-IC (SoIC) dies, which are composite dies having vertically stacked dies. In this way, 2.5D structures that have SoIC dies may also be viewed as 3D structures. Depending on the processes adopted, the 2.5D structure and the 3D structure may have an Integrated Fan-Out (InFO) construction or a Chip-on-Wafer-on-Substrate (CoWoS®) construction.

In the embodiment shown, the semiconductor package 100 includes a package substrate 610, an interposer 606 over the package substrate 610, multiple dies 200 over the interposer 606, a liquid metal 504 over the dies 200, and a heat sink 506 over the liquid metal 504. The dies 200 are bonded to the interposer 606 via micro-bumps 604, and the interposer 606 is bonded to the package substrate 610 via controlled collapse chip connection (C4) bumps 608. The dies 200 are laterally surrounded by an underfill 609a that lands on the interposer 606. The interposer 606 is laterally surrounded by an underfill 609b that lands on the package substrate 610. A molding compound 303 is disposed adjacent and surrounds edge dies 200 and lands on the interposer 606. A molding compound 305 is disposed adjacent the molding compound 303, the interposer 606, and the underfill 609b, and lands on the package substrate 610. A ring structure 500 lands on the molding compound 305 and is configured to support and contain the liquid metal 504. The ring structure 500 also supports the heat sink 506. These and other various features are described in more detail below.

The package substrate 610 generally refers to a wafer or semiconductor structure that acts as a carrier base for an IC package. This carrier base may also be generally referred to as a base substrate, a substrate underlayer, or the like. In an embodiment, the package substrate 610 includes a semiconductor substrate formed of silicon, silicon germanium, silicon carbon, or the like. The package substrate 610 may have various package components mounted thereon, such as one more interposers 606, one or more dies 200, and/or one or more other active or passive chip devices such as one or more surface mount (SMT) components 402. The SMT components 402 may be SMT capacitors. The package substrate 610 may further include redistribution layers formed therein, and the redistribution layers route signals from die components (e.g., dies 200) and chip devices (e.g., SMT components 402) onto a printed circuit board (PCB) (not shown).

The semiconductor package 100 may be part of a bigger IC structure. For example, the semiconductor package 100 may be mounted onto a PCB (not shown). In this case, the package substrate 610 may include a ball-grid array (BGA) structure on its back side. The BGA structure includes solder joints 611 that may bond one or more semiconductor packages 100 onto the PCB. The PCB may include multiple other IC components mounted thereon, thereby forming a processor, a controller, a memory unit, or other electronic modules.

The interposer 606 generally refers to a redistribution layer (RDL) structure that electrically connects one or more dies 200 to each other and/or to another structure (e.g., package substrate 610). The interposer 606 may be a silicon interposer or an organic interposer. The interposer 606 may include conductive traces 607 that route electrical signals between dies 200 and/or between dies 200 and the package substrate 610. The conductive traces 607 may include various metal lines extending laterally and various metal vias extending vertically. The metal vias vertically connects the metal lines. The conductive traces 607 are embedded in one or more passivation layers. The passivation layers are insulating layers for isolating different signal paths.

The interposer 606 is bonded and electrically connected to the package substrate 610 via one or more C4 bumps 608. The C4 bumps 608 are disposed on a back side of the interposer 606. The C4 bumps 608 are interconnect bumps and may include solder bumps or copper pillar (CuP) bumps. The solder bumps may include tin, lead, and/or silver, and the CuP bumps may include a copper pillar having a solder cap at the end. The solder cap may be made of tin, lead, and/or silver. The C4 bumps 608 may land on bonding pads of the package substrate 610.

The interposer 606 may further include one or more interposer components 404 mounted on a backside thereon. The interposer components 404 may be capacitor chips. The interposer components 404 may be bonded and electrically connected to the interposer 606 (or conductive traces 607 thereof) through redistribution layers (RDLs) 270 and interposer bumps 612. Specifically, each interposer component 404 may include a top RDL 270 having conductive traces, and electrical signals are routed from the top RDL 270 to the interposer 606 via the interposer bumps 612. The respective RDLs 270 may include landing pads as part of an aluminum pad layer. Through-silicon-vias (TSVs) may also be used to vertically route signals through the interposer 606.

The dies 200 are bonded to and electrically connected to the interposer 606 via one or more micro-bumps 604. The micro-bumps 604 are disposed on a back side of the dies 200. Like the C4 bumps 608, the micro-bumps 604 are interconnect bumps and may include solder bumps or copper pillar (CuP) bumps. The solder bumps may include tin, lead, and/or silver, and the CuP bumps may include a copper pillar having a solder cap at the end. The solder cap may be made of tin, lead, and/or silver. The difference between the C4 bumps 608 and the micro-bumps 604 is that the micro-bumps 604 may have a smaller width in the x and/or y direction. The micro-bumps 604 may be attached to landing pads of the dies 200 on one side and landing pads of the interposer 606 on the other side. The landing pads of the dies 200 may be part of an aluminum pad layer. And the aluminum pad layer may be part of (or extend from) an RDL 270 of the dies 200.

FIG. 1 illustrates two dies 200 disposed along the x direction, however in other embodiments, more or less dies 200 may be present. Multiple dies 200 may also be disposed along the y direction (not shown). The dies 200 may be formed of various active and/or passive devices (e.g., transistor devices, resistors, capacitors, carrier substrate, etc.). For the present embodiments, the dies 200 may be SoC dies, SoIC dies, logic dies, application specific integrated circuit (ASIC) dies, HBM dies, or other types of dies/chips. In the embodiment shown, the dies 200 are disposed adjacent to each other in the lateral direction. In another embodiment, the dies 200 may be stacked on top of each other in the vertical direction. In yet another embodiment, the dies 200 may be disposed adjacent each other and also stacked on top of each other to form various integrated stacked structures.

Each of the dies 200 may include a device layer sandwiched between various IC layers and components (e.g., sandwiched between a frontside interconnect structure and a backside interconnect structure). The device layer is where device-level features such as transistor devices are formed. The transistor devices may be logic devices, memory devices, or the like. Each of the transistor devices includes a channel region between source/drain (S/D) regions and a gate stack over the channel regions. The device layer may further include other device-level features such as S/D contacts, S/D vias, gate contacts, and/or gate vias, each of which may electrically connect the S/D regions and/or the gate stacks to a higher or lower material layer of the dies (e.g., frontside and/or backside interconnect structures). The dies 200 may include a frontside interconnect structure over the device layer and a backside interconnect structure under the device layer. The frontside and backside interconnect structures may include metal lines and vias embedded in intermetal dielectric (IMD) layers, and the metal lines and vias route signals to and from the transistor devices in the device layer. In an embodiment, as part of (or separate from) the dies 200, a bonding layer is disposed over the frontside interconnect structure, and a carrier substrate is disposed over the bonding layer. For example, the bonding layer and the carrier substrate (e.g., made of silicon) are formed to provide structural support when forming the backside interconnect structure.

The dies 200 may be bonded and electrically connected to the interposer 606 (or conductive traces 607 thereof) through bottom RDLs 270 and micro-bumps 604. Specifically, each die 200 may include a bottom RDL 270 having conductive traces, and electrical signals are routed from the RDL 270 to the interposer 606 via the bonded connection at the micro-bumps 604. The respective RDLs 270 may include landing pads as part of an aluminum pad layer. The micro-bumps 604 may be attached to landing pads of the RDLs 270 on one side and landing pads of the interposer 606 on the other side. Note that for vertically stacked die structures (e.g., SoIC dies), through-silicon-vias (TSVs) may be used to vertically route signals between stacked dies.

The underfill 609a and 609b are encapsulants that provide structural and mechanical support between the package substrate 610 and the interposer (see underfill 609b) and between the interposer 606 and the dies 200 (see underfill 609a). The underfill 609a and 609b also mechanically strengthen and surround the micro-bumps 604 and the C4 bumps 608. In an embodiment, the underfill 609a and 609b may be made of composite material such as an epoxy polymer. In an embodiment, the underfill 609a and 609b may be a liquid encapsulant such as epoxy resins infused with silica particles. The molding compound 303 lands on the interposer 606 and is disposed along sidewalls of the underfill 609a and/or the edge dies 200. The molding compound 303 surrounds the underfill 609a to provide additional structural support to the dies 200 encapsulated by the underfill 609a. The molding compound 305 lands on the package substrate 610 and is disposed along sidewalls of the molding compound 303, the interposer 606, and the underfill 609b. The molding compound 305 may also encapsulate the one or more SMT components 402. The molding compounds 303 and 305 may include similar materials as the underfill 609a and underfill 609b. In an embodiment, the molding compounds 303 and 305 includes epoxy resins, phenolic hardeners, silicas, catalysts, pigments, and/or mold release agents. In some embodiments, the molding compounds 303 are 305 are more structurally rigid than the underfills 609a and 609b for securing onto the interposer 606. The molding compound 303, molding compound 305, underfill 609a, and the underfill 609b collectively prevents mechanical fatigue by providing stress redistribution.

Notably, the molding compound 305 provides support for the ring structure 500 formed thereon. Further, the molding compound 305 acts as an insulator to electrically isolate the SMT components 402 and prevent them from shorting to the ring structure 500.

The liquid metal 504 lands on a top surface of the dies 200, the molding compound 303, and the molding compound 305. The liquid metal 504 acts as a heat conduit and distributor on a front side of the respective dies 200. Specifically, the liquid metal 504 acts as a thermal interface material (TIM) layer to direct heat from device hot spots (e.g., hot spots in the dies 200) towards a heat sink (e.g., heat sink 506). TIM layer(s) are generally used as an interface material to improve heat transfer between a heat source (e.g., an IC chip or die) and a heat sink (e.g., heat-spreading lid). Liquid metal 504 is a superior TIM layer due to its extremely high thermal conductivity compared to traditional TIM layer(s) (e.g., thermal paste), which generally include a polymer, resin, or epoxy as a base material, and a filler to improve its thermal conductivity.

In the present embodiment, the liquid metal 504 is a liquid in a pure or alloy state at room temperature. For example, the liquid metal 504 may include gallium or a gallium alloy, aluminum or an aluminum alloy, or mercury or a mercury alloy. The liquid metal 504 may have a thermal conductivity greater than 50 W/m/K. The liquid metal 504 may have a thermal resistance less than 10° C./W. The liquid metal directly interfaces top surfaces of the dies 200 and simultaneously acts as a heat spreader interface and a secondary heat sink (e.g., liquid heat-spreading lid) covering a large surface area of the semiconductor package 100. A primary heat sink (e.g., heat sink 506) is placed over the liquid metal 504. To support and contain the liquid metal 504, the ring structure 500 defines an interior die area where the liquid metal 504 is filled.

The ring structure 500 is attached onto a top surface of the molding compound 305 through base adhesive joints 605 (or seal glue layer) to glue the ring structure 500 onto the molding compound 305. The base adhesive joints 605 may be made of any suitable material (e.g., epoxy, adhesive tapes, etc.). The ring structure 500 surrounds and holds the liquid metal 504 in place. Further details of the ring structure 500 will be described with respect to later figures.

The heat sink 506 is attached to the ring structure 500 through another layer of base adhesive joints 605. Besides acting as the primary heat sink, the heat sink 506 acts as a cap or cover for the semiconductor package 100. The heat sink 506 absorbs and dissipates any heat coming from components of the dies 200. The heat sink 506 absorbs heat from the dies 200 through the liquid metal 504. The heat sink 506 directly contacts and dips into the liquid metal 504. The heat sink 506 is formed of a metal or a metal alloy, which has a high thermal conductivity, for example, higher than about 100 W/m/K. For example, the heat sink 506 may be formed of a metal, or a metal alloy selected from Al, Cu, Ni, Co, stainless steel, and alloys thereof. Further details of the heat sink 506 will be described with respect to later figures.

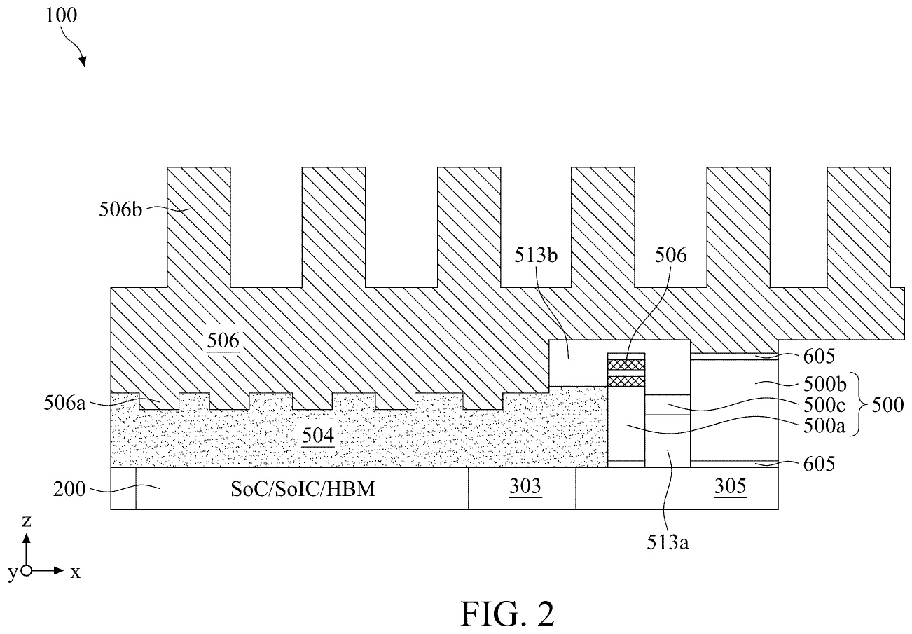

FIG. 2 illustrates a portion of the IC semiconductor package 100 of FIG. 1, according to an embodiment of the present disclosure. In the present embodiment, the liquid metal 504 lands on an entire top surface of the dies 200, an entire top surface of the molding compound 303, and a partial top surface of the molding compound 305. Specifically, the liquid metal 504 is contained by inner sidewalls of the ring structure 500, which lands on the molding compound 305 (e.g., via adhesive joints 605). The heat sink 506 is secured onto the ring structure 500 (e.g., via adhesive joints 605) and lands on and interfaces the liquid metal 504. The heat sink 506 includes bottom grooves 506a (or fins) formed from cavities that cut into a bottom surface of the heat sink 506. The liquid metal 504 fills the cavities to surround the grooves 506a for maximized thermal contact and interface between the liquid metal 504 and the heat sink 506. As shown, the heat sink 506 directly contacts and dips into the liquid metal 504 such that the liquid metal 504 fills into the cavities between the bottom grooves 506a. The heat sink 506 further includes elongated protrusions 506b (or fins) that extend from a top surface of the heat sink 506. The elongated protrusions 506b offer improved air circulation to cool down the heat sink 506.

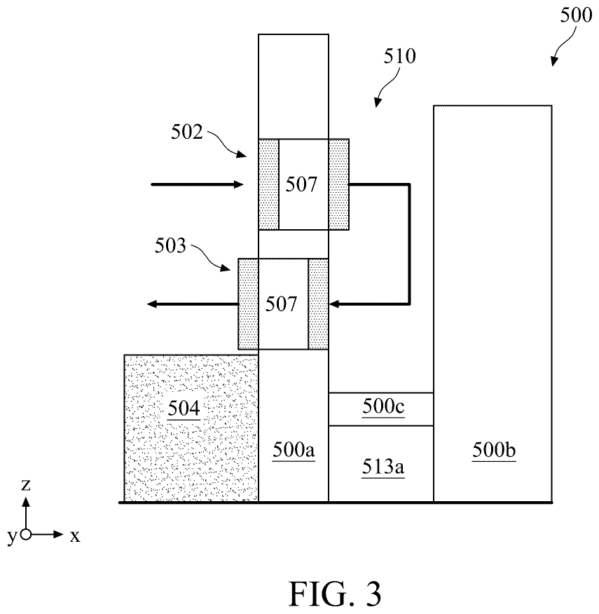

As described in more detail below, the ring structure 500 includes an inner ring portion 500a interfacing the liquid metal 504 and an outer ring portion 500b supporting the heat sink 506. The inner ring portion 500a includes through holes 507 for circulating the liquid metal 504 when thermal or physical stress is applied during device operation, thereby preventing liquid metal overflow or leakage. The inner ring portion 500a and the outer ring portion 500b may be connected by a bridge portion 500c. The bridge portion 500c secures the inner ring portion 500a to the outer ring portion 500b. In the embodiment shown, there is a bottom gap 513a under the bridge portion 500c and a top gap 513b above the bridge portion 500c. The bottom gap 513a and the top gap 513b help to prevent delamination effects by providing air cushion during device operation. During device operation, package components may thermally expand and thermally contract, causing warpage and bending. However, when structures are rigid, such warpage and bending may cause delamination and defects (such as breakage of connections). As such, the bottom gap 513a and top gap 513b allows for flexible space to account for the possible warpage and bending. In the present embodiment, the top gap 513b exposes top and side surfaces of the inner ring portion 500a. The top gap 513b also exposes a bottom surface and side surface of the heat sink 506 for improved air cooling of the heat sink 506. In other words, the top gap 513b functions as an air gap that separates the inner ring portion 500a from the heat sink 506. Portions of the top gap 513b also form a buffer area 510 (see FIG. 3) for temporarily holding liquid metal 504 as part of a liquid metal circulation mechanism via the through holes 507.

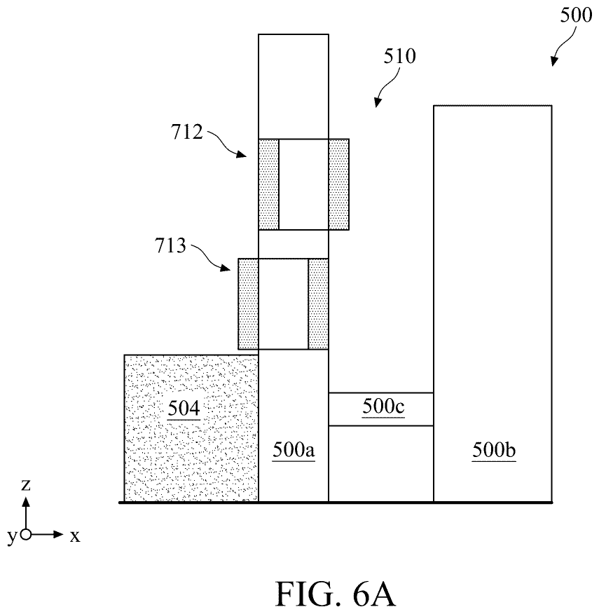

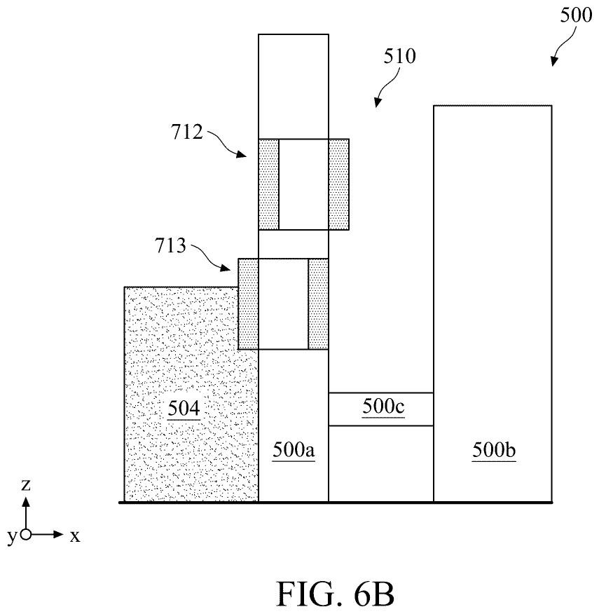

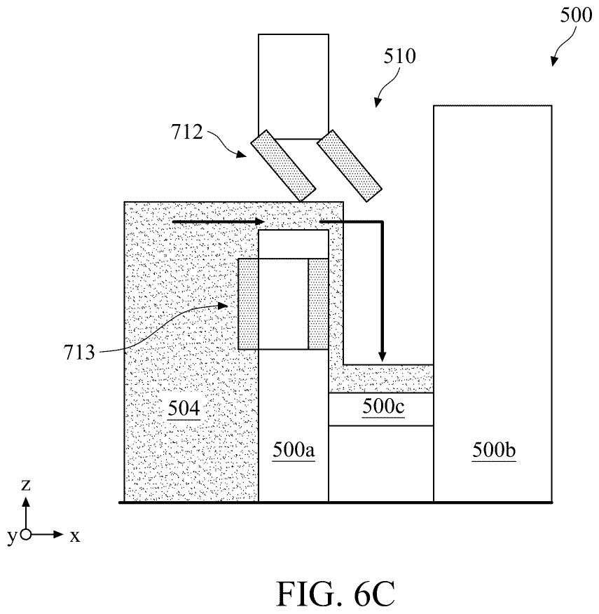

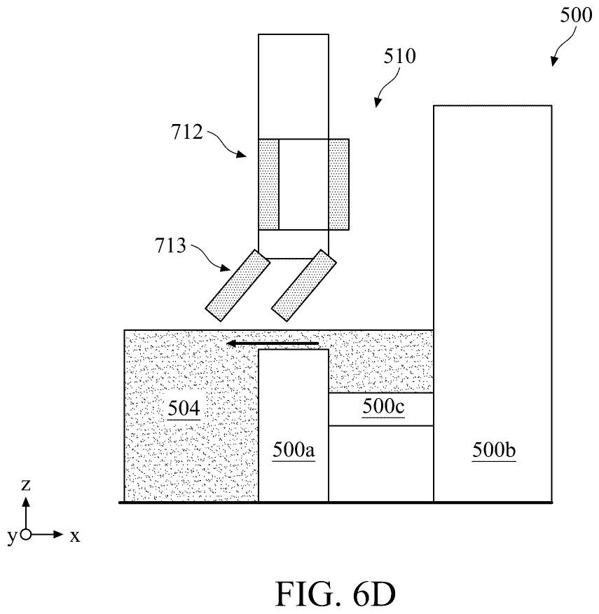

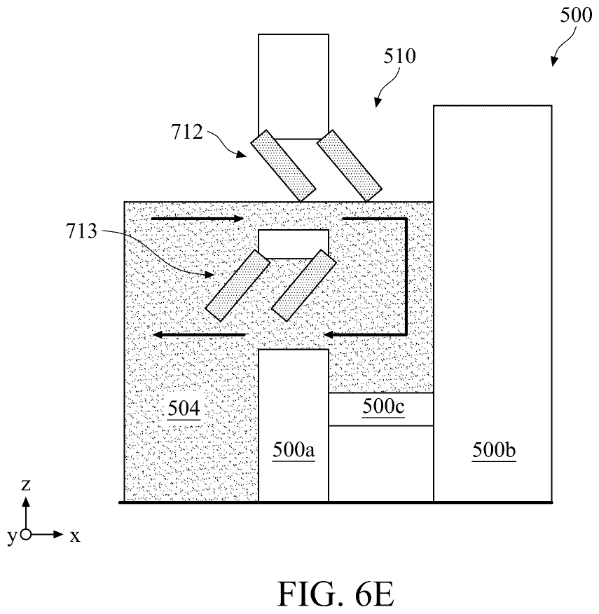

FIG. 3 illustrates a ring structure 500 for supporting liquid metal 504 over dies 200, according to an embodiment of the present disclosure. The ring structure 500 has a built-in liquid metal circulation mechanism for containing the liquid metal 504 when thermal stress and physical stress is applied, which may cause liquid metal level to rise and fall, as will be demonstrated in reference to FIGS. 6A-6E. As shown, the ring structure 500 includes the inner ring portion 500a connected to the outer ring portion 500b by a bridge portion 500c. The inner ring portion 500a, the outer ring portion 500b, and the bridge portion 500c may be distinct structures formed separately, or they may be formed together as a composite structure. The bottom gap 513a exposes bottom side surfaces of the inner ring portion 500a, the outer ring portion 500b, and a bottom surface of the bridge portion 500c. A buffer area 510 is formed above the bridge portion 500c in between the inner ring portion 500a and the outer ring portion 500b. The buffer area 510 acts as a temporary reservoir for holding excess liquid metal 504 that overflow under thermal and/or physical stress.

Still referring to FIG. 3, the inner ring portion 500a includes through holes 507 that define a top circulation channel 502 and a bottom circulation channel 503. The top circulation channel 502 includes or is coupled to an inlet valve, and the bottom circulation channel 503 includes or is coupled to an outlet valve. As demonstrated by the arrows, when liquid metal level rises and begins to overflow, the excess liquid metal 504 flows in a one way direction into the buffer area 510 through the top circulation channel 502 and out of the buffer area 510 through the bottom circulation channel 503. For example, the inlet valve is a one-way valve configured to let liquid metal 504 into the buffer area 510 but not out of the buffer area 510, and the outlet valve is another one-way valve configured to let liquid metal 504 out of the buffer area 510 but not into the buffer area 510. The inlet valve is above the outlet valve, such that the liquid metal 504 flows into the buffer area 510 at a greater height and flows out of the buffer area 510 at a smaller height.

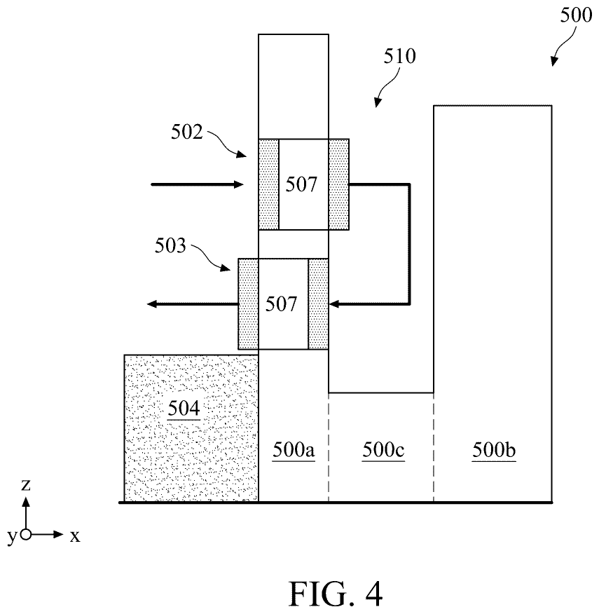

FIG. 4 illustrates a ring structure 500 for supporting liquid metal 504 over dies 200, according to another embodiment of the present disclosure. The ring structure 500 of FIG. 4 is similar to the ring structure 500 of FIG. 3, except that the bottom gap 513a is eliminated. Instead, the bridge portion 500c extends continuously downwards. As such, the ring structure 500 may be viewed as a single structure with two portions protruding from a base. In this embodiment, the ring structure 500 may be more structurally sound for a stronger base support. On the other hand, the elimination of the bottom gap 513a takes away an air cushion, which may increase stress points when physical and thermal stress is applied. In some cases, this will not be an issue since the buffer area 510 also acts as an air cushion for added structural flexibility. In other words, the buffer area 510 not only function to temporally hold excess liquid metal 504, but it may also provide room for thermal expansion to prevent delamination when the package is under stress.

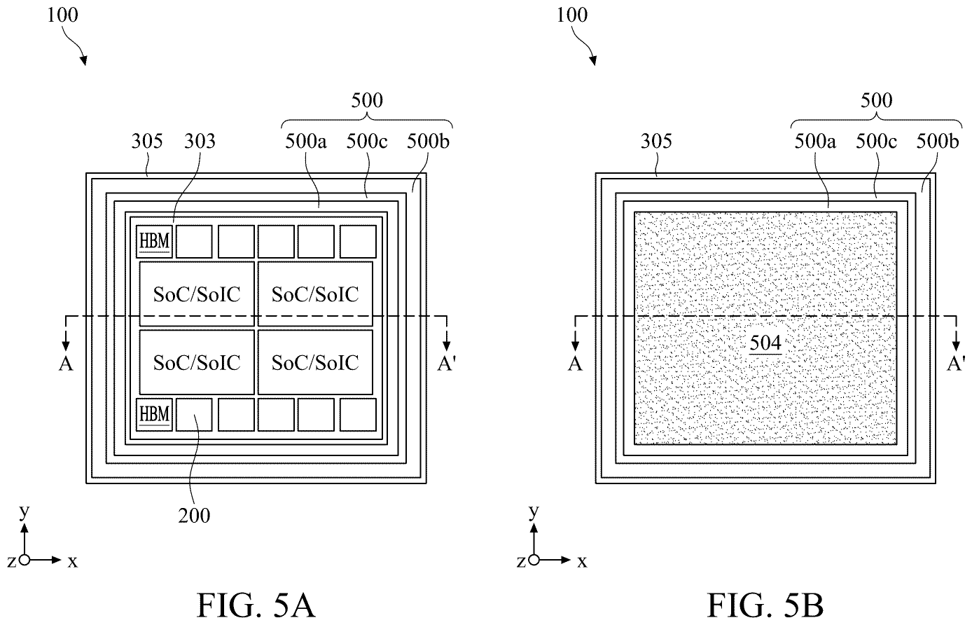

FIGS. 5A-5B illustrate various top views of the IC semiconductor package 100 of FIG. 1, according to various embodiments of the present disclosure. The IC semiconductor package 100 of FIG. 1 may be a cross-section of the semiconductor package 100 of FIGS. 5A-5B cut along the lines A-A′. FIG. 5A illustrates a top view without the liquid metal 504 over the dies 200, and FIG. 5B illustrates a top view with the liquid metal 504 over the dies 200. As shown, various dies 200 (e.g., HBM, SoC/SoIC), are located in a die area of the semiconductor package 100. In the embodiment shown, SoC/SoIC dies are located towards the center area of the die area, and the HBM dies are located in the peripheral area of the die area, but the present disclosure is not limited thereto. The dies 200 are surrounded by and embedded in the molding compound 303, which holds the dies 200 in place. The molding compound 303 is then surrounded by the molding compound 305. The ring structure 500 lands on the molding compound 305 and is disposed along perimeters of the semiconductor package 100 (e.g., surrounding the die area on all four sides). In some embodiments (e.g., as shown in FIG. 3), only the inner ring portion 500a and the outer ring portion 500b lands on the molding compound 305, while the bridge portion 500c suspends in air. In some embodiments (e.g., as shown in FIG. 4), each of the inner ring portion 500a, the outer ring portion 500b, and the bridge portion 500c lands on the molding compound 305. Referring to FIG. 5B, the liquid metal 504 is disposed and dispensed on the die area and contained by the inner ring portion 500a of the ring structure 500. As such, the liquid metal 504 may also cover the molding compound 303 and inner portions of the molding compound 305.

FIGS. 6A-6E illustrate a mechanism of containing liquid metal 504 using inlet and outlet valves in a ring structure 500, according to an embodiment of the present disclosure. For illustrative purposes, and referencing FIG. 3, the top circulation channel 502 having the top through hole 507 and the inlet valve is collectively referred to as the inlet channel 712, and the bottom circulation channel 503 having the bottom through hole 507 and the outlet valve is collectively referred to as the outlet channel 713.

Starting at FIG. 6A, at an equilibrium state, the liquid metal 504 has a top surface below a bottom surface of the outlet channel 713. In this state, no valve mechanisms are triggered, and the liquid metal 504 remains in place.

Referencing FIG. 6B, as liquid metal level begins to rise due to thermal or physical stress (e.g., under device operation), the liquid metal 504 may rise to a level such that a top surface of the liquid metal 504 is above the bottom surface of the outlet channel 713 but below a bottom surface of the inlet channel 712. In this state, the liquid metal 504 still remains in place since the outlet valve of the outlet channel 713 only allows liquid metal 504 to flow out of the buffer area 510 but not into the buffer area 510. In this way, liquid metal 504 is prevented from flowing into the buffer area 510 even as the liquid metal 504 rises to above the outlet channel 713.

Referencing FIG. 6C, as liquid metal level continues to rise, the liquid metal 504 may rise to a level such that a top surface of the liquid metal 504 is above a bottom surface of the inlet channel 712. In this state, the liquid metal 504 begins flowing into the buffer area 510 via the inlet channel 712. This is because the inlet valve of the inlet channel 712 will open up when it senses the liquid metal reaching the level of the inlet channel 712. As shown, the liquid metal 504 may then overflow into the buffer area 510 by landing on the bridge portion 500c.

Referencing FIG. 6D, as liquid metal 504 flows into the buffer area 510, the liquid metal level may start to decrease. Further, as the buffer area 510 becomes filled up with liquid metal 504, the liquid metal 504 on the buffer side may rise to a level above a bottom surface of the outlet channel 713. When this happens, the liquid metal 504 in the buffer area 510 is dispensed and flows out of the buffer area 510 via the outlet valve of the outlet channel 713. This is because the outlet valve of the outlet channel 713 will open up when it senses the liquid metal reaching the level of the outlet channel 713 on the buffer side. As shown, the excess liquid metal 504 may then flow back into the input side of the liquid metal 504.

Referencing FIG. 6E, in some cases, high thermal stress will cause the liquid metal 504 to rise to very high levels such that both the inlet valve of the inlet channel 712 and the outlet valve of the outlet channel 713 are activated. In such a case, liquid metal 504 is both flown into and out of the buffer area 510 as shown.

As illustrated from FIGS. 6A-6E, the rising and falling of the liquid metal level may be dynamic, and the inlet channel 712, the outlet channel 713, and the buffer area 510 of the ring structure 500 allows control and circulation of the liquid metal 504 to account for any fluctuations of liquid metal 504 when it is under thermal or physical stress.

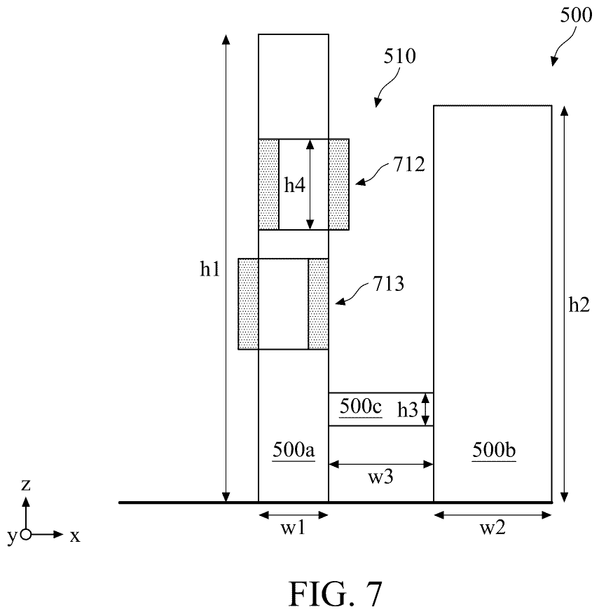

FIG. 7 illustrates various dimensions of a ring structure 500 for supporting liquid metal 504 over dies 200, according to an embodiment of the present disclosure. As shown here, and also previously described, the ring structure 500 may include an inner ring portion 500a having an inlet channel 712 and an outlet channel 713, an outer ring portion 500b, a bridge portion 500c connecting between the inner ring portion 500a and the outer ring portion 500b, and a buffer area 510 defined by the space above the bridge portion 500c and between the inner ring portion 500a and the outer ring portion 500b. The inner ring portion 500a is configured to directly interface and contain the liquid metal 504. The inlet channel 712 and outlet channel 713 are configured to circulate the liquid metal 504 into and out of the buffer area 510 via inlet and outlet valves that control the respective channels.

In an embodiment, a top surface of the outer ring portion 500b is above the top surface of the inlet channel 712. This ensures liquid metal 504 that flows into the buffer area 510 is stopped by the inner sidewall of the outer ring portion 500b. However, the present disclosure is not limited thereto, for example, the inlet channel 712 may be higher, equal to, or lower than the top surface of the outer ring portion 500b, as long as liquid metal 504 does not escape the ring structure 500 and is contained within the buffer area 510.

In an embodiment, the bottom surface of the outlet channel 713 is above the top surface of the bridge portion 500c. This allows for an amount of liquid metal 504 to accumulate in the buffer area 510 before the liquid metal 504 flows back into the input side of the liquid metal 504. In another embodiment, a top surface of the bridge portion 500c is substantially coplanar with the bottom surface of the outlet channel 713. This prevents any liquid metal loss being trapped in the buffer area 510 (i.e., the outlet valve of the outlet channel 713 will be activated upon liquid metal 504 landing on the bridge portion 500c).

In an embodiment, when the semiconductor package 100 is not under physical or thermal stress (e.g., see FIG. 6A), a bottom surface of the outlet channel 713 is above a top surface of the liquid metal 504. This ensures liquid metal 504 is always contained during an equilibrium state when no inlet or outlet valves are activated.

The inner ring portion 500a has a height h1, the outer ring portion has a height h2, and the height h1 may be greater than, equal to, or less than the height h2. In an embodiment, the heights h1 and/or h2 may range between about 3 mm to about 10 mm. Each of the inlet channel 712 and outlet channel 713 may have a channel height h4. In an embodiment, the height h4 ranges between about 0.1 mm to about 3 mm.

The inner ring portion 500a has a width w1, and the outer ring portion has a width w2. In an embodiment the width w1 ranges between about 3 mm to about 10 mm. In an embodiment the width w2 ranges between about 5 mm to about 30 mm. In an embodiment, the width w2 is greater than the width w1 because a greater width w2 better supports the heat sink 506 attached thereon. That is, the outer ring portion 500b is the structural support portion of the ring structure 500, and thus can be wider than the inner ring portion 500a. Conversely, the inner ring portion 500a only function to contain the liquid metal 504 and does not contact the heat sink 506. As such, the width of the inner ring portion 500a can be minimized as long as it supports the liquid metal 504.

The bridge portion 500c has a height h3 and a width w3. The height h3 is less than the heights h1 and h2 to create the buffer area 510. In an embodiment, the height h3 ranges between about 0.5 mm to about 5 mm. The width w3 defines the width of the buffer area 510 (i.e., space between the inner ring portion 500a and the outer ring portion 500b). In an embodiment, the width w3 ranges between about 0.5 mm to about 5 mm.

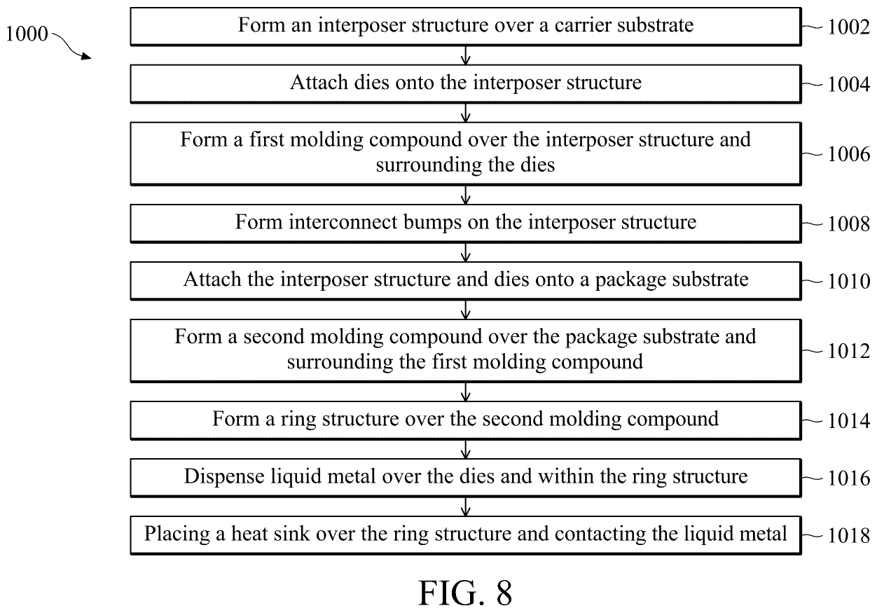

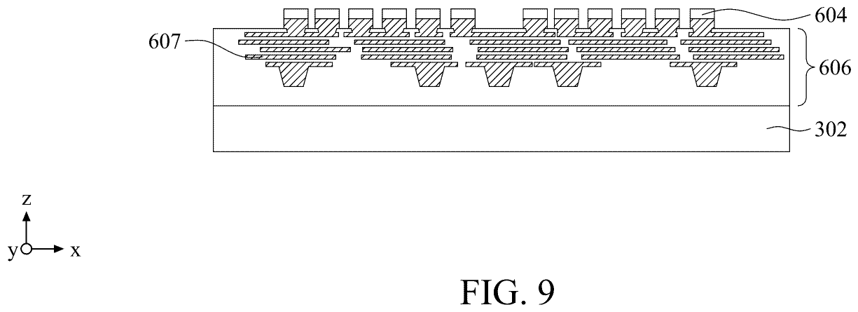

FIG. 8 illustrates a flow chart of a method 1000 to form an IC semiconductor package 100 having a ring structure 500 for supporting liquid metal 504 over dies 200, in portion or in entirety, according to an embodiment of the present disclosure. FIGS. 9-15 illustrate an IC semiconductor package 100 (or a portion thereof) at intermediate stages of fabrication and processed in accordance with the method 1000 of FIG. 8, according to an embodiment of the present disclosure. Method 1000 is merely an example and is not intended to limit the present disclosure to what is explicitly illustrated. Additional steps can be provided before, during and after method 1000 and some steps described can be replaced, eliminated, or moved around for additional embodiments of the method. Not all steps are described herein in detail for reasons of simplicity. Method 1000 is described below in conjunction with FIGS. 9-15. Similar features previously described may equally apply to features shown in FIGS. 9-15. As such, not all features in FIGS. 9-15 are described herein in detail for reasons of simplicity.

Referring to FIG. 9, the method 1000 at operation 1002 forms an interposer structure (e.g., interposer 606) over a carrier substrate 302. The carrier substrate 302 may be a silicon substrate. The interposer structure may be temporarily bonded to the carrier substrate 302 for structural support, and the carrier substrate 302 may be debonded in a later step. The interposer structure includes passivation structures surrounding and isolating conductive traces 607 (such as vias, metal lines, and/or landing pads). The interposer structure further includes micro-bumps 604 formed thereover for bonding to other external structures (e.g., dies 200).

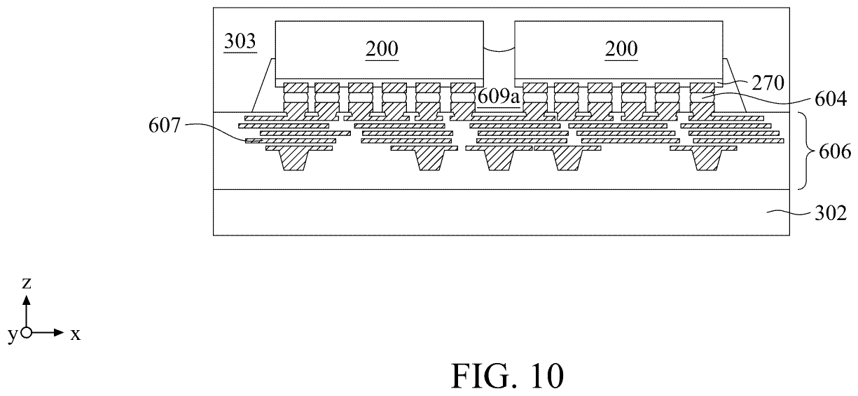

Referring to FIG. 10, the method 1000 at operation 1004 attaches dies 200 onto the interposer structure (e.g., interposer 606). As shown, multiple dies 200 are bonded to the interposer 606 via the micro-bumps 604. The multiple dies 200 may be formed in a separate manufacturing process that includes forming device structures on a wafer and dicing the wafer into chips. The chips may then be processed to form the different dies 200. The method 1000 at operation 1004 may further form an underfill (e.g., underfill 609a) to fill gaps between the dies 200 and between the dies 200 and the interposer 606.

Still referring to FIG. 10, the method 1000 at operation 1006 forms a first molding compound 303 over the interposer structure (e.g., interposer 606) and surrounding the dies 200. The first molding compound 303 laterally surrounds the underfill 609a, and at this stage, the first molding compound 303 may also cover top surfaces of the underfill 609a and dies 200.

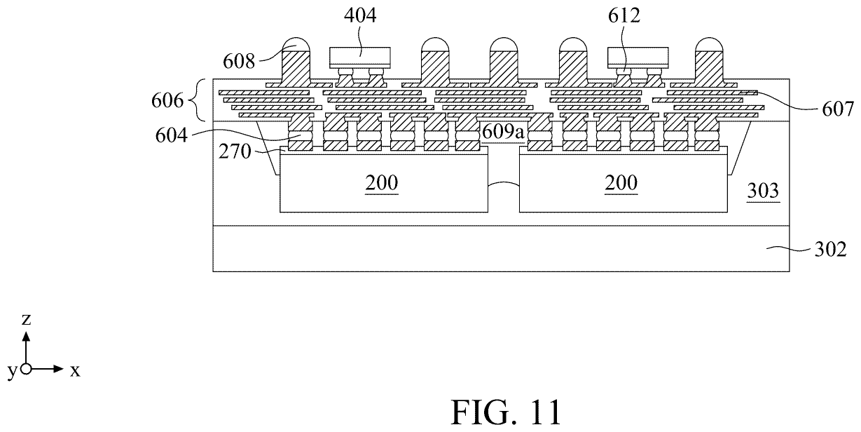

Referring to FIG. 11, the method 1000 at operation 1008 forms interconnect bumps (e.g., C4 bumps 608) on the interposer structure (e.g., interposer 606). The method 1000 at operation 1008 may include a bonding and/or a debonding process to attach/detach carrier substrates 302 for appropriate backside processing of the interposer structure. The backside processing may include etching back the interposer structure (e.g., interposer 606) to expose landing pads and/or conductive traces 607 and forming the C4 bumps 608 on the landing pads and/or conductive traces 607. As part of operation 1008, interposer components 404 may be formed and bonded to interposer bumps 612 on a back side of the interposer structure.

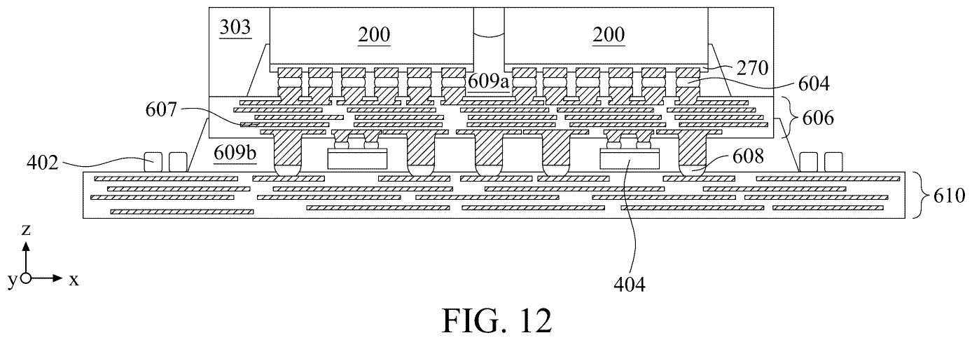

Referring to FIG. 12, the method 1000 at operation 1010 attaches the interposer structure (e.g., interposer 606) and dies 200 onto a package substrate 610. The interposer 606 may be attached via the C4 bumps 608 landing on and bonding to landing pads of the package substrate 610. Thereafter, as part of operation 1012, the method 1000 may form an underfill (e.g., underfill 609b) to fill gaps between the C4 bumps 608 and interposer components 404 and between the interposer 606 and the package substrate 610. The underfill 609b laterally surrounds the interposer 606. Further, as part of operation 1012, carrier substrate 302 may be detached and a top surface of the first molding compound 303 may be planarized such that top surfaces of the dies 200 are exposed. As such, the top surfaces of the dies 200 may be substantially coplanar with top surfaces of the first molding compound 303.

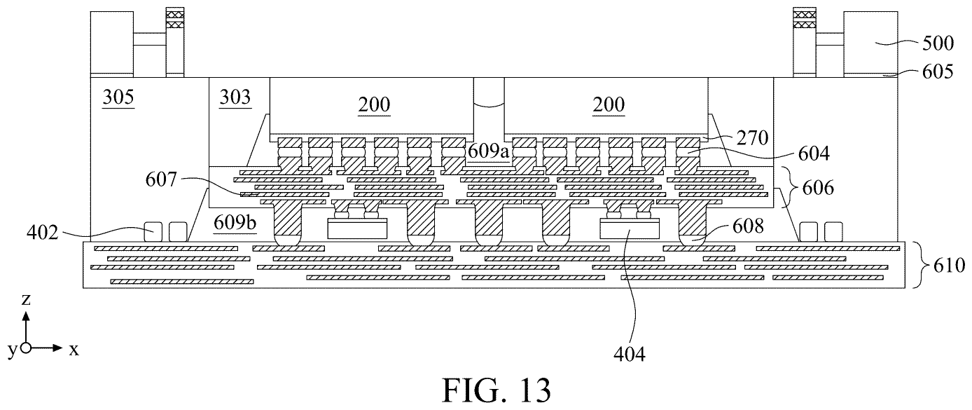

Referring to FIG. 13, the method 1000 at operation 1012 forms a second molding compound 305 over the package substrate 610 and surrounding the first molding compound 303. The second molding compound 305 covers a top surface of the package substrate 610 and may further embed SMT components 402 formed on the package substrate 610. As part of operation 1012, a top surface of the workpiece may be planarized such that top surfaces of the dies 200, the first molding compound 303, and the second molding compound 305 are substantially coplanar.

Still referring to FIG. 13, the method 1000 at operation 1014 forms a ring structure 500 over the second molding compound 305. The ring structure 500 may be mounted onto the second molding compound via adhesive joints 605 as shown. Details of the ring structure 500 were previously described and will not be repeated again for the sake of brevity.

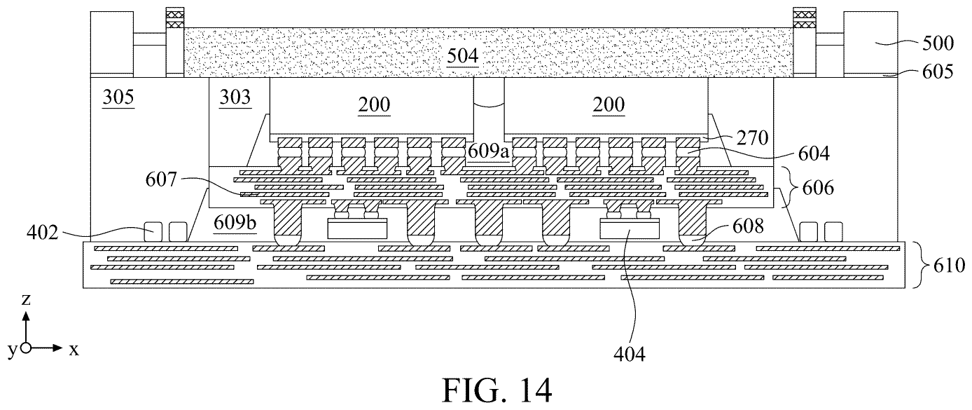

Referring to FIG. 14, the method 1000 at operation 1016 dispenses liquid metal 504 over the dies 200 and within the ring structure 500 (i.e., in a die area contained by inner sidewalls of the ring structure 500). The liquid metal 504 may be dispense by any suitable process and lands on top surfaces of the dies 200, the first molding compound 303, and the second molding compound 305.

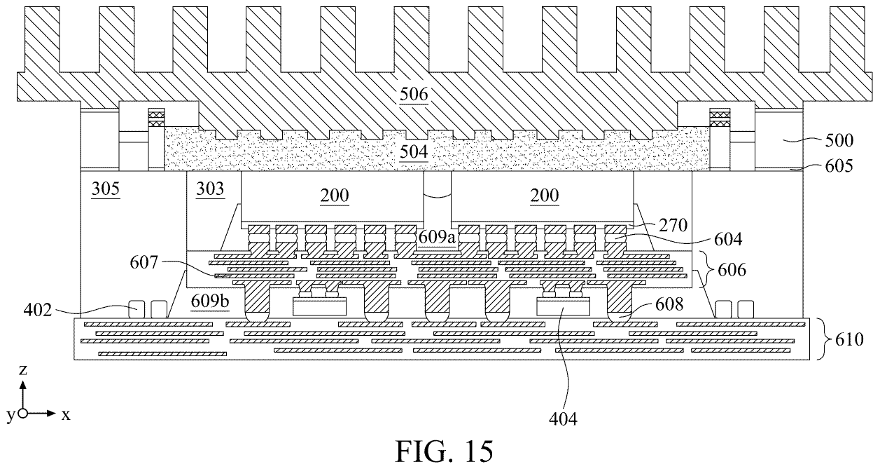

Referring to FIG. 15, the method 1000 at operation 1018 places a heat sink 506 over the ring structure 500 and contacting the liquid metal 504. The heat sink 506 may include protrusions that dip into the liquid metal 504 for maximized surface contact and pin fins that protrude upwards for optimum heat dissipation and cooling. The protrusions (e.g., grooves 506a previously described) and pin fins (e.g., elongated protrusions 506b previously described) may be formed before the operation 1018. The heat sink 506 is placed and mounted over the liquid metal 504 via base adhesive joints 605 over outer sidewalls of the ring structure 500.

Although not limiting, the present disclosure offers advantages for semiconductor packages. One example advantage is to incorporate liquid metal as a thermal interface material for improved thermal performance. Another example advantage is to incorporate a ring structure to support and contain the liquid metal. Another example advantage is to incorporate a buffer area in the ring structure to account for liquid metal level fluctuations, and to recirculate liquid metal as the liquid metal rises and falls during device operation. Another example advantage is to incorporate an outer molding compound to support the ring structure and to electrically isolate electrical components on a package substrate from the ring structure. Another example advantage is to configure a heat sink to directly contact the liquid metal, and the liquid metal to directly contact the dies. In this way, the number of thermal interfaces is decreased, further improving thermal performance.

One aspect of the present disclosure pertains to a package structure. The package structure includes a die bonded to a substrate; a molding compound over the substrate and surrounding the die; a liquid metal over a top surface of the die; a ring structure over the molding compound and surrounding sidewalls of the liquid metal; and a heat sink attached to the ring structure and contacting the liquid metal. The ring structure includes an inner ring portion interfacing the liquid metal and an outer ring portion supporting the heat sink, and the inner ring portion includes through holes that form circulation channels for the liquid metal.

In an embodiment, the ring structure further includes a buffer area between the inner ring and the outer ring, the buffer area is configured to hold portions of the liquid metal that flow through the circulation channels. In a further embodiment, the ring structure further includes a bridge portion connecting the inner ring portion to the outer ring portion, and a top surface of the bridge portion defines a bottom surface of the buffer area.

In an embodiment, the circulation channels includes: a top channel coupled to an inlet valve; and a bottom channel coupled to an outlet valve, where the liquid metal is configured to flow into the buffer area through the top channel and out of the buffer area through the bottom channel. In a further embodiment, the inlet valve is a one-way valve configured to let liquid metal into the buffer area but not out of the buffer area, and the outlet valve is another one-way valve configured to let liquid metal out of the buffer area but not into the buffer area.

In an embodiment, the heat sink include cavities that cut into a bottom surface of the heat sink, and the liquid metal fills the cavities. In an embodiment, the liquid metal directly contacts the die, and the heat sink directly contacts the liquid metal.

In an embodiment, the package structure further includes one or more surface mount (SMT) components on the substrate, wherein the molding compound covers the SMT components and electrically isolates the one or more SMT components from the ring structure.

In an embodiment, an air gap separates the inner ring portion from the heat sink.

Another aspect of the present disclosure pertains to a package structure. The package structure includes a die bonded to a substrate; a liquid metal over a top surface of the die; and a ring structure surrounding sidewalls of the liquid metal. The liquid metal is constrained in an area between inner sidewalls of the ring structure. The ring structure includes: an inner ring having a top through hole coupled to an inlet valve and a bottom through hole coupled to an outlet valve, an outer ring surrounding the inner ring, a bridge connecting the inner ring to the outer ring, and a buffer area over the bridge and disposed between the inner ring and the outer ring, where the buffer area is configured to collect a portion of the liquid metal that flows through the inlet valve and dispense a portion of the liquid metal that flows through the outlet valve.

In an embodiment, a top surface of the liquid metal is below a bottom surface of the bottom through hole.

In an embodiment, a top surface of the liquid metal is above a bottom surface of the bottom through hole but below a bottom surface of the top through hole.

In an embodiment, a top surface of the liquid metal is above a bottom surface of the top through hole.

In an embodiment, the liquid metal lands on a top surface of the bridge.

In an embodiment, the package structure further includes a heat sink attached to the ring structure and contacting the liquid metal, where the heat sink is mounted on the outer ring and separated from the inner ring.

In an embodiment, the package structure further includes a molding compound over the substrate and surrounding the die, where the ring structure is mounted onto the molding compound, and the liquid metal lands on portions of the molding compound.

Another aspect of the present disclosure pertains to a package structure. The package structure includes an interposer structure disposed over a substrate; a die disposed over the interposer structure; a first molding compound disposed over the interposer structure and surrounding the die; a second molding compound disposed over the substrate and surrounding the first molding compound; a liquid metal landing on the die, the first molding compound, and the second molding compound; a ring structure on the second molding compound and surrounding the liquid metal, the liquid metal constrained between sidewalls of the ring structure; and a heat sink on the ring structure and dipping into the liquid metal.

In an embodiment, the heat sink has top fins that protrude above a base and bottom fins that protrude below the base, and the liquid metal surrounds the bottom fins.

In an embodiment, the ring structure includes an inner ring interfacing the liquid metal and an outer ring supporting the heat sink, and the inner ring includes through holes that form circulation channels for the liquid metal. In a further embodiment, the ring structure further includes a bridge portion connecting the inner ring to the outer ring, and a top and a bottom surface of the bridge is exposed to air.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a die bonded to a substrate;
a molding compound over the substrate and surrounding the die;
a liquid metal over a top surface of the die;
a ring structure over the molding compound and surrounding sidewalls of the liquid metal; and
a heat sink attached to the ring structure and contacting the liquid metal,
wherein the ring structure includes an inner ring portion interfacing the liquid metal and an outer ring portion supporting the heat sink, and the inner ring portion includes through holes that form circulation channels for the liquid metal.

2. The package structure of claim 1, wherein the ring structure further includes a buffer area between the inner ring and the outer ring, the buffer area is configured to hold portions of the liquid metal that flow through the circulation channels.

3. The package structure of claim 2, wherein the ring structure further includes a bridge portion connecting the inner ring portion to the outer ring portion, and a top surface of the bridge portion defines a bottom surface of the buffer area.

4. The package structure of claim 2, wherein the circulation channels includes:
a top channel coupled to an inlet valve; and
a bottom channel coupled to an outlet valve, wherein the liquid metal is configured to flow into the buffer area through the top channel and out of the buffer area through the bottom channel.

5. The package structure of claim 4, wherein the inlet valve is a one-way valve configured to let liquid metal into the buffer area but not out of the buffer area, and the outlet valve is another one-way valve configured to let liquid metal out of the buffer area but not into the buffer area.

6. The package structure of claim 1, wherein the heat sink include cavities that cut into a bottom surface of the heat sink, and the liquid metal fills the cavities.

7. The package structure of claim 1, wherein the liquid metal directly contacts the die, and the heat sink directly contacts the liquid metal.

8. The package structure of claim 1, further comprising:
one or more surface mount (SMT) components on the substrate, wherein the molding compound covers the SMT components and electrically isolates the one or more SMT components from the ring structure.

9. The package structure of claim 1, wherein an air gap separates the inner ring portion from the heat sink.

10. A package structure, comprising:
a die bonded to a substrate;
a liquid metal over a top surface of the die; and
a ring structure surrounding sidewalls of the liquid metal, wherein the liquid metal is constrained in an area between inner sidewalls of the ring structure,
wherein the ring structure includes:
an inner ring having a top through hole coupled to an inlet valve and a bottom through hole coupled to an outlet valve,
an outer ring surrounding the inner ring,
a bridge connecting the inner ring to the outer ring, and
a buffer area over the bridge and disposed between the inner ring and the outer ring, wherein the buffer area is configured to collect a portion of the liquid metal that flows through the inlet valve and dispense a portion of the liquid metal that flows through the outlet valve.

11. The package structure of claim 10, wherein a top surface of the liquid metal is below a bottom surface of the bottom through hole.

12. The package structure of claim 10, wherein a top surface of the liquid metal is above a bottom surface of the bottom through hole but below a bottom surface of the top through hole.

13. The package structure of claim 10, wherein a top surface of the liquid metal is above a bottom surface of the top through hole.

14. The package structure of claim 10, wherein the liquid metal lands on a top surface of the bridge.

15. The package structure of claim 10, further comprising:
a heat sink attached to the ring structure and contacting the liquid metal, wherein the heat sink is mounted on the outer ring and separated from the inner ring.

16. The package structure of claim 10, further comprising:
a molding compound over the substrate and surrounding the die, wherein the ring structure is mounted onto the molding compound, and the liquid metal lands on portions of the molding compound.

17. A package structure, comprising:
an interposer structure disposed over a substrate;
a die disposed over the interposer structure;
a first molding compound disposed over the interposer structure and surrounding the die;
a second molding compound disposed over the substrate and surrounding the first molding compound;
a liquid metal landing on the die, the first molding compound, and the second molding compound;
a ring structure on the second molding compound and surrounding the liquid metal, the liquid metal constrained between sidewalls of the ring structure; and
a heat sink on the ring structure and dipping into the liquid metal.

18. The package structure of claim 17, wherein the heat sink has top fins that protrude above a base and bottom fins that protrude below the base, and the liquid metal surrounds the bottom fins.

19. The package structure of claim 17, wherein the ring structure includes an inner ring interfacing the liquid metal and an outer ring supporting the heat sink, and the inner ring includes through holes that form circulation channels for the liquid metal.

20. The package structure of claim 19, wherein the ring structure further includes a bridge portion connecting the inner ring to the outer ring, and a top and a bottom surface of the bridge is exposed to air.
